(19) United States
(12) Patent Application Publication
(10) Pub. No.: US 2012/0273972 A1
(43) Pub. Date: Nov. 1, 2012

(54) SEMICONDUCTOR DEVICE

(75) Inventor: Yosuke KAWAI, Kanagawa (JP)

(73) Assignee: Renesas Electronics Corporation, Kanagawa (JP)

(21) Appl. No.: 13/452,799

(22) Filed: Apr. 20, 2012

(30) Foreign Application Priority Data
Apr. 26, 2011 (JP) 2011-097777

(51) Int. Cl. H01L 23/498

(52) U.S. Cl. 257/777; 257/E23.06

(57) ABSTRACT

Mounting a power supply ring-shaped conductor and a ground ring-shaped conductor within the innermost circumferential ring-shaped area enclosing the semiconductor chip and within the ring-shaped region adjacent to the outer side of this innermost circumferential ring-shaped region when mounting the semiconductor chip on the substrate package, makes the chip more resistant to noise but also conversely causes the problem of increased cost and size for the entire semiconductor device. The power supply pad and ground pad are here clustered in the outermost ring-shaped area on the semiconductor chip. The power supply terminal and ground terminal are clustered on the innermost ring-shaped region enclosing the semiconductor chip. This placement reduces the size and manufacturing cost of the overall semiconductor device.

### CROSS-REFERENCE TO RELATED APPLICATIONS

The disclosure of Japanese Patent Application No. 2011-097777 filed on Apr. 26, 2011 including the specification, drawings and abstract is incorporated by reference in its entirety.

### BACKGROUND

The present invention relates to a semiconductor device and relates in particular to a semiconductor device in which the semiconductor chip is mounted over the package substrate.

Semiconductor devices and in particular the field of multifunction semiconductor devices such as SoC (System On a Chip) must provide an ever-increasing number of functions on the internal semiconductor chip. A greater number of semiconductor chip functions require a larger total number of pads for the input and output of signals for those functions. Increasing the number of pads normally necessitates a larger semiconductor chip and semiconductor package size.

Yet at the same time, the manufacturing cost of the semiconductor device must also be reduced. Accomplishing these goals requires technical advances in the semiconductor chip manufacturing process to shrink the size of the semiconductor chip. Achieving these mutually exclusive conditions necessitates miniaturizing the semiconductor chip and package substrate while cutting the cost of the overall semiconductor device.

A semiconductor integrated circuit relating to this technology is disclosed in Japanese Unexamined Patent Publication No. 2000-252363. In the layout of this semiconductor integrated circuit, multiple I/O buffer regions utilized during input and output of signals to and from external sections, and for input from external power supplies are mounted in the periphery of the core region where the desired circuits are formed. A feature of this semiconductor integrated circuit is that at least one power supply pad and ground pad, and a signal pad for inputting and outputting signals to and from external sections are mounted perpendicular to the scribe line over the outer circumference of the chip nearest to the I/O buffer region, and arrayed in rows within the applicable I/O buffer region.

Japanese Unexamined Patent Publication No. 2001-244293 discloses technology relating to a semiconductor element. Over the main surface of this semiconductor element, multiple signal electrodes utilized for input or output of signals are arrayed along the sides of the main surface. A feature of this semiconductor element is that power supply or ground electrodes are arrayed at a length longer than the applicable signal electrodes between the signal electrodes and the sides of the main surface.

Japanese Unexamined Patent Publication No. 2003-133470 discloses technology relating to a package. The package is comprised of a substrate and a semiconductor chip. The substrate includes an upper surface over which are mounted a ground ring, a power ring, and a conductive trace. The semiconductor chip mounted over the upper surface includes multiple bonding pads along the periphery. These bonding pads include innermost bonding pads, inner row bonding pads, outer row bonding pads, and outermost row bonding pads arrayed in at least four rows. The innermost row bonding pads and inner row bonding pads are comprised of signal pads. The outer row bonding pads and outermost row bonding pads are comprised of power pads and ground pads.

Japanese Unexamined Patent Publication No. 2008-311379 discloses technology relating to a semiconductor device. In this semiconductor device, semiconductor elements are mounted over the package, and wire bonding couples the semiconductor elements to the package. In this semiconductor device, reference voltage pads are mounted over the inner side of the signal pads over the upper surface of the semiconductor elements. In this semiconductor device, reference voltage pads are mounted over the outer side of the signal pads over the upper surface of the package. In this semiconductor device, bonding wires at reference voltage potential coupling the reference voltage pads on the semiconductor elements to the reference voltage pads of the package are mounted above the signal bonding wires coupling the signal pads of the package to the signal pads over the semiconductor element.

Japanese Unexamined Patent Publication No. 2009-004528 discloses technology relating to a semiconductor device. This semiconductor device includes a semiconductor chip and a mounting substrate. The semiconductor chip is a chip having multiple electrode pads functioning as the signal pads and power supply pads. The mounting substrate includes the semiconductor chip mounted over the surface, along with multiple stitches electrically coupled to electrode pads by conductive wires. In this semiconductor device, the mounting substrate includes multiple mounting electrodes comprised of signal electrodes and power supply electrodes arrayed along the rear side, and each mounting electrode is respectively electrically coupled to a stitch by way of internal wiring. The electrode pads are comprised of inner pads arranged over the inner side along the periphery of the semiconductor chip, and outer pads arrayed over that external side. This semiconductor device includes sub-electrode pads over the inner region of the electrode pads that are configured as power supply pads among the inner pads.

Japanese Unexamined Patent Publication No. 2010-010492 discloses technology relating to a semiconductor device. This semiconductor device is comprised of a semiconductor substrate, a mounting substrate, multiple pads, multiple wires, and multiple wire bonding parts. Here, a circuit is formed over the semiconductor substrate. The mounting substrate is coupled to the rear side of the semiconductor substrate. The pads are electrically coupled to the circuit corresponding to the signal, the power supply voltage, and the reference voltage, and are arrayed linearly perpendicular to the rim edge nearest within the main surface of the semiconductor substrate. The wires is coupled at one end to the pads. The wire bonding parts formed over the mounting substrate is coupled at the other ends of the wires. The signal pads for input and output of signals are mounted over the side farthest from the edge within the pad row where the pads are linearly arrayed. Among the wire bonding parts, the signal wire bonding parts for input and output of signals are installed at positions over the mounting substrate farther from the semiconductor substrate than the other wire bonding parts.

### SUMMARY

FIG. 1 is a flat view showing an outline pictorial diagram of the structure of a fragment of the semiconductor device of the related art. FIG. 1 is a drawing of the structure with changes made to the reference numerals and names of the structural elements based on FIG. 8 of Japanese Unexamined Patent Publication No. 2003-133470. The structure of the semiconductor device according to the related art shown in FIG. 1 is described next.

A ground ring terminal 130 is mounted over the ring-shaped region at the innermost circumference enclosing the semiconductor chip 110 on the package substrate 112. A power supply ring-shaped terminal 140 is mounted over the ring-shaped region adjacent to the outer side of the ground ring-shaped terminal 130. A signal terminal 160 is mounted in the outer side of the power supply ring-shaped terminal 140.

Each type of pads 120 is grouped into at least quadruple ring-shaped regions over the semiconductor chip 110. A ground pad 121 is arrayed here over in the ring-shaped region at the outermost circumference. A power supply pad 122 is arrayed over the ring-shaped region at the outer circumference adjacent to the inner side of the outermost circumference. Signal pads 123 and 124 are respectively mounted over the ring-shaped region of the inner circumference adjacent to the inner side of the ring-shaped region of the outer circumference, and the ring-shaped region at the innermost circumference adjacent to the inner side of the ring-shaped region of the outer circumference.

A first bonding wire 121a couples the ground pad 121 to the ground ring-shaped terminal 130. A second bonding wire 122a couples the power supply pad 122 to the power supply ring-shaped terminal 140. A third bonding wire 123a couples the signal pad 123 in the inner circumferential ring-shaped region to the signal ring-shaped terminal 160. A fourth bonding wire 124a couples the signal pad 124 in the innermost circumferential ring-shaped region to the signal ring-shaped terminal 160.

In a semiconductor device of the related art shown in FIG. 1, utilizing the above structure, the total number of ground pads 121 and power supply pads 122 can be increased as well as increasing the total number of bonding wires 120a at the same time. This arrangement allows improved resistance to noise in the power supply. Moreover, the size of the semiconductor chip can be reduced compared to previous chips of the related art.

However, the overall semiconductor device utilizing the technology of the related art shown in FIG. 1 cannot achieve a lower cost. A first reason is that the package substrate surface area must be made larger in order to obtain the two ring-shaped regions for the power supply ring-shaped terminal 140 and the ground ring-shaped terminal 130. A second reason is that the surface area of the semiconductor device must be increased in order to obtain two ring-shaped regions for the power supply pad 122 and the ground pad 121. These regions are needed because the circuits cannot be mounted directly beneath the pads 121-124 over the semiconductor chip and is especially critical in cases where the semiconductor chip surface area is not dependent on the pads 121-124. A third reason is that the number of bonding wires is increased to boost the noise resistance and so the total length of the bonding wires increases and costs are higher.

The method for resolving the problems of the related art is hereinafter described while utilizing the reference numerals used in the embodiments (Detailed Description of the Preferred Embodiments). These reference numerals were added to clarify the interrelation between the description (What is claimed is) and the embodiments (Detailed Description of the Preferred Embodiments). However these reference numerals must not be utilized to interpret the technical range of the invention as described in the claims (What is claimed is).

According to one aspect of the present invention, the semiconductor device includes a semiconductor chip (10) and a package substrate (20). The semiconductor chip (10) is here comprised of power supply pads (11), ground pads (12), and signal pads (13-15). The package substrate (20) contains the semiconductor chip (10). The package substrate (20) is comprised of a first terminal group (21, 22) and a second terminal group (23-25). The first terminal group (21, 22) is arrayed in a ring-shaped region at the innermost circumference along the periphery of the semiconductor chip (10). The second terminal group (23-25) is arrayed over the periphery of the semiconductor chip (10), and further over the outer side of the innermost circumference of the ring-shaped region. The first terminal group (21, 22) is comprised of a power supply terminal group (21), and a ground terminal group (22). Here, the power supply group (21) is coupled by way of the bonding wires to the power supply pads (11). The ground terminal group (22) is coupled by way of the bonding wires to the ground pads (12). The second terminal group (23-25) is comprised of a signal terminal group (23-25) coupled by way of the bonding wires to the signal pads (13-15).

According to the aspects of the present invention, in the semiconductor device, the power supply and ground terminals at the periphery of the semiconductor chip over the package substrate can be mounted in one row portion of ring space. The technology of the related art requires a two-row portion of ring space so that the semiconductor device can be reduced in size by an equivalent amount, the overall length of the bonding wires can be shortened, and therefore a lower cost can be achieved.

### BRIEF DESCRIPTION OF THE DRAWINGS

FIG. 1 is a flat view showing an outline pictorial diagram of the structure of a fragment of the semiconductor device of the related art;

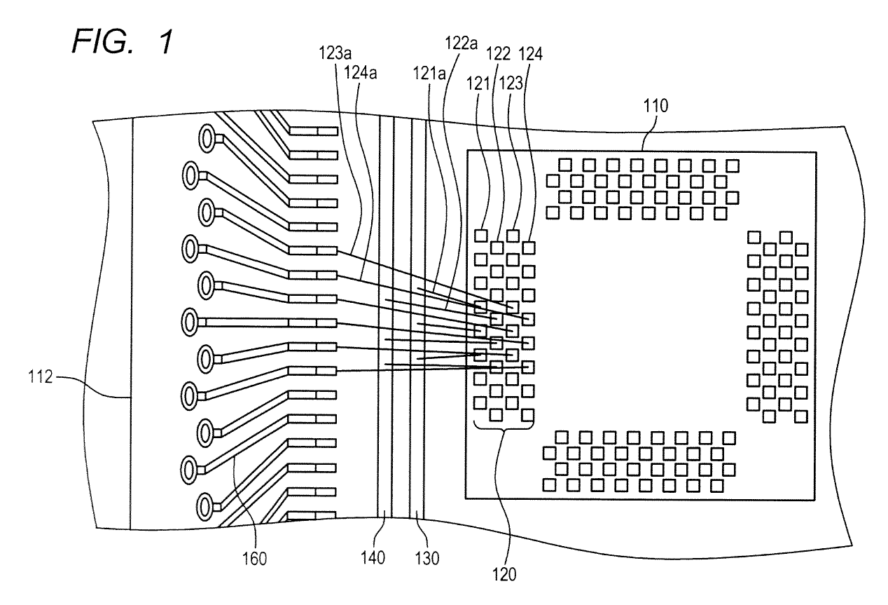

FIG. 2A is a flat view showing the broad overall structure of the semiconductor device according to a first embodiment of the present invention;

FIG. 2B is a frontal view showing the broad overall structure of the semiconductor device according to the first embodiment of the present invention;

FIG. 3 is a flat view showing in detail a fragment of the structure of the semiconductor device according to the first embodiment of the present invention;

FIG. 4A is a flat view showing an example of mounting the various terminal types and various pad types over the semiconductor device of the related art;

FIG. 4B is a flat view showing an example of mounting the various terminal types and various pad types over the semiconductor device according to the first embodiment of the present invention;

FIGS. 5A and 5B are a group of flat views showing the difference in semiconductor device sizes in the technology of the related art and the present invention;

FIGS. 6A and 6B are a group of flat views showing the difference in semiconductor device sizes in the technology of the related art and the present invention;

FIG. 7 is a flat view showing a fragment of the structure of the semiconductor device according to a second embodiment of the present invention;

FIG. 8 is a flat view showing a fragment of the structure of the semiconductor device according to a third embodiment of the present invention; and

FIG. 9 is a flat view showing a fragment of the structure of the semiconductor device according to a fourth embodiment of the present invention.

### DETAILED DESCRIPTION OF THE PREFERRED EMBODIMENTS

The embodiments for implementing the semiconductor device of the present invention are described next while referring to the drawings.

### First Embodiment

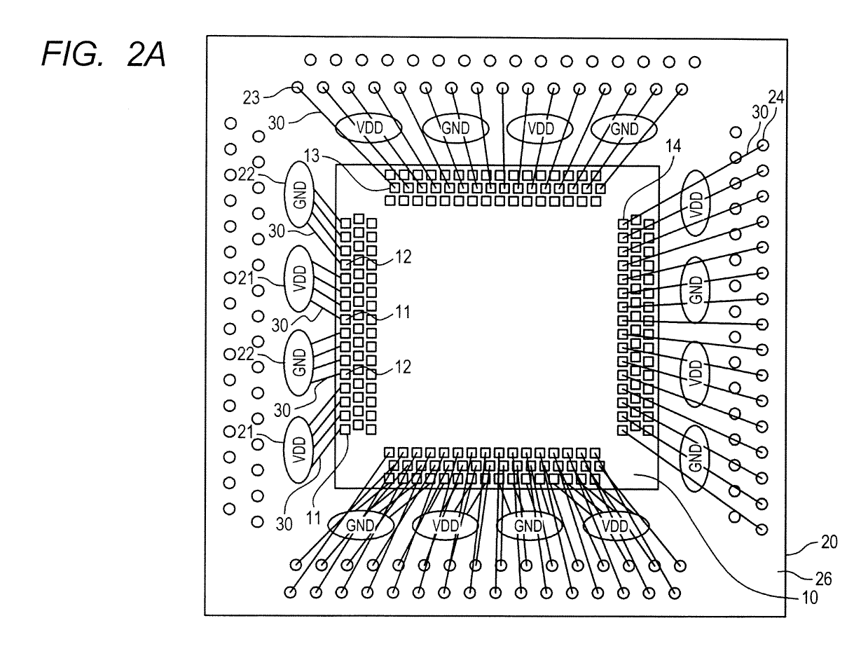

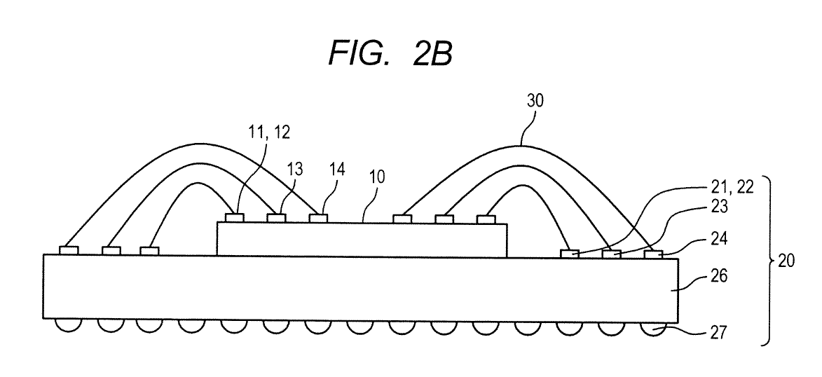

FIG. 2A is a flat view showing the broad overall structure of the semiconductor device according to a first embodiment of the present invention. FIG. 2B is a frontal view showing the broad overall structure of the semiconductor device of the first embodiment of the present invention. The structural elements of the semiconductor device in FIG. 2A and FIG. 2B are described next. The semiconductor device of FIG. 2A and FIG. 2B is comprised of a semiconductor chip 10, a package substrate 20, and a bonding wire 30. The semiconductor chip 10 is comprised of a power supply pad 11, a ground pad 12, and the signal pads 13, 14. The package substrate 20 is comprised of a power supply terminal 21, a ground terminal 22, the signal terminals 23, 24, a laminated substrate 26, and a BGA (Ball Grid Array) 27. The laminated substrate 26 is comprised of a conducting layer, an insulation layer, a contact hole and so on the same as commonly used, however there are no particular specifications otherwise. Moreover, the surface of the laminated substrate 26, and the surface area for mounting the semiconductor chip 10 may include a circuit formed by conductive patterns but there are no particular specifications otherwise.

The coupling relation of the structural elements in the semiconductor device in FIG. 2A and FIG. 2B is described next. In FIG. 2A a portion of the bonding wire 30 is omitted. In other words, in FIG. 2A, only the bonding wires 30 for the ground pad 12 and the power supply pad 11 are shown on the left side, only the bonding wires 30 for the signal pad 13 are shown on the top side, only the bonding wires 30 for the signal pad 14 are shown on the right side, and all the bonding wires 30 are shown on the bottom side. Actually however, all of the bonding wires 30 shown on the bottom side are also present on the left side, the top side, and the right side.

The power supply pad 11 and the ground pad 12 are mounted at the outermost circumference of the ring-shaped region over the semiconductor chip 10. The power supply terminal 21 and the ground terminal 22 are mounted at the innermost circumference of the ring-shaped region over the package substrate 20.

The power supply pad 11 is coupled by way of the bonding wire 30 to the power supply terminal 21 over the package substrate 20. Multiple power supply pads 11 may here be jointly coupled to the same power supply terminal 21. The power supply terminal 21 jointly coupled in this way to multiple power supply pads 11 are here called the joint power supply terminals 21 to distinguish them from the power supply terminal 21 coupled in a one-to-one relation to a single power supply pad 11. The reason for jointly coupling multiple power supply pads 11 by way of one joint power supply terminal 21 amounts to nothing more than for each bonding wire to convey a signal of the same electrical potential; and also because there is no need to deal with noise problems due to crosstalk, even if the respective gaps between wires are close to each other compared to the bonding wire for normal signals.

The ground pad 12 is coupled by way of the bonding wire 30 to the ground terminal 22 over the package substrate 20. Multiple ground pads 12 may here be jointly coupled to the same ground terminal 22. The power terminals 22 jointly coupled to the ground pads 12 are here called joint ground terminals 22 to distinguish them from the ground terminals 22 coupled in a one-to-one relation to a single ground pad 12.

A portion of the signal pads 13 are formed in the ring-shaped region adjacent to the inner side of the outermost circumferential ring-shaped region over the semiconductor chip 10. Other signal pads 14 are mounted in the ring-shaped region at the innermost circumference over the semiconductor chip 10. A portion of the signal terminals 23 are mounted in the ring-shaped region adjacent to the outer side of the ring-shaped region at the innermost circumference over the package substrate 20. Other signal terminals 24 are mounted in the ring-shaped region at the outermost circumference of the package substrate 20. The signal pads 13 are coupled by way of the bonding wire 30 to the signal terminal 23 of the package substrate 20. The signal pads 14 are coupled by way of the bonding wire 30 to the signal terminal 24 of package substrate 20. The reason for jointly coupling multiple ground pads 12 to one joint ground terminal 22 amounts to nothing more than for each bonding wire to convey a signal of the same electrical potential; and also because there is no need to deal with noise problems due to crosstalk, even if the respective gaps between wires are close to each other compared to the bonding wire for normal signals.

The joint power terminals 21, joint ground terminals 22 and the signal terminals 23, 24 over the package substrate 20 are coupled by way of contact holes and conductive layers to the BGA27 the same as in ordinary cases and there are no particular specifications here otherwise.

The total number of pads 11-14, the total number of terminals 21-24, the total number of ring-shaped region and the total number of ring-shaped regions over the package substrate given here are at most merely examples and do not limit the present invention.

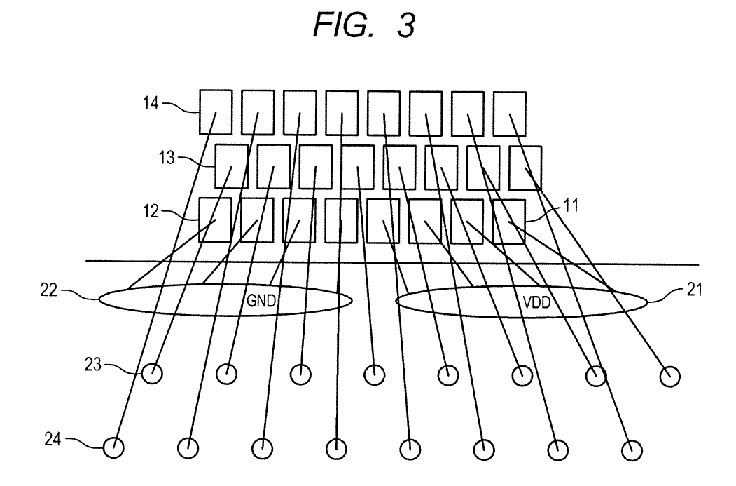

FIG. 3 is a flat view showing in detail a fragment of the structure of the semiconductor device of the first embodiment of the present invention. The flat view in FIG. 3 shows a portion of the semiconductor chip 10, a portion of the power supply pads 11, a portion of the ground pads 12, a portion of the signal pads 13, a portion of the package substrate 20, a portion of the joint power supply terminals 21, a portion of the joint ground terminals 22, a portion of the signal terminals 23, and a portion of the bonding wires 30.

In one ideal example of the present embodiment, the size of the joint power supply terminal 21 along the arrayed direction is made some several times longer than the length of the signal terminals 23 in order that multiple power supply pads 11 can be jointly coupled to one joint power supply terminal 21. The size of the joint ground terminal 22 along the array direction is in the same way made several times longer than the length of the signal terminals 23, in order that multiple ground pads 12 can be jointly coupled to one joint ground terminal 22. This placement allows eliminating the gap that would ordinarily be provided between the adjacent terminals 21-24, and also leads to further downsizing of the semiconductor device. Stated in more general terms, the surface area of each of the joint power supply terminals 21 subjected to bonding by the bonding wire is larger than the bonding surface area at each of the signal terminals 23. In the same way, the surface area of each joint ground terminal 22 bonded by the bonding wire has a bonding wire surface area that is larger than the bonding surface area over each signal terminal 23 bonded by the bonding wire.

The power supply terminals 21 and the ground terminals 22 moreover are mounted alternately along the ring-shaped region at the innermost circumference over the package substrate 20. This placement reduces the offset of the power supply terminals 21 and the ground terminals 22 mounted along the periphery of the semiconductor chip 10, and increases the degree of freedom for internal circuit design within the semiconductor chip 10.

By combining all of these measures, the power supply pad 11 over the semiconductor chip 10 are clustered together by coupling them to the same power supply terminal 21. The ground pads 12 over the semiconductor chip 10 are in the same way clustered together by coupling them to the same ground terminal 22.

The pads 11, 12, and 13 over the semiconductor chip 10 are preferably arrayed offset in every other ring-shaped region so as to achieve an overall so-called staggered (zigzag) layout. Making this placement allows easily avoiding contact and electrical shorts between the bonding wires 30.

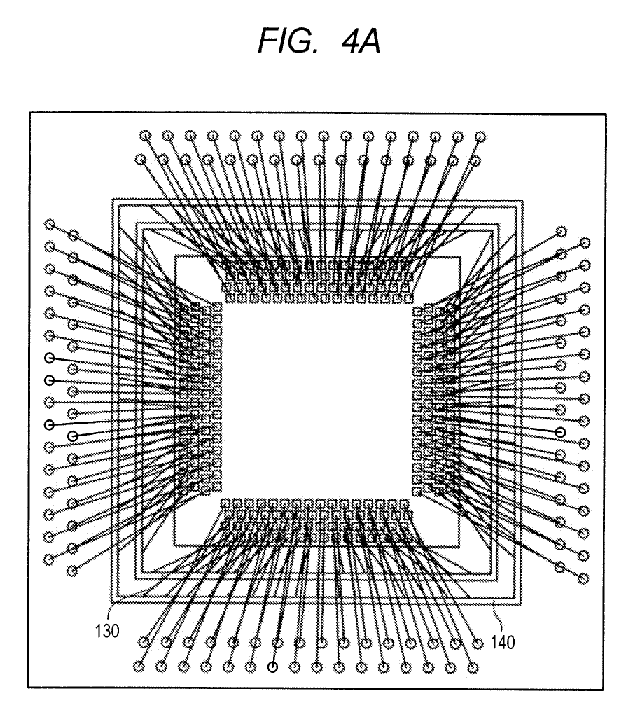

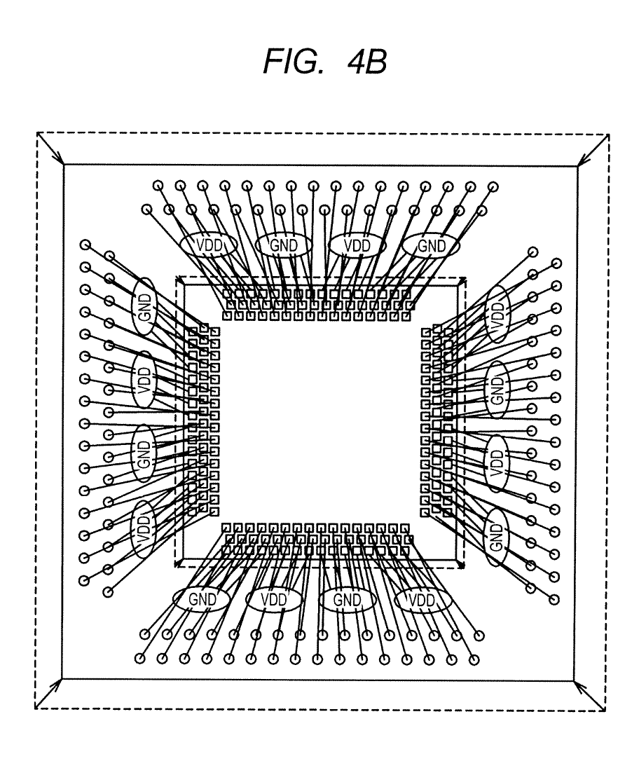

FIG. 4A is a flat view showing an example of mounting the various pads 11, 12, and 13 as well as the various terminal types 21, 22, 23, and 24 over the semiconductor device of the related art. FIG. 4B is a flat view showing an example of mounting the various pads 11, 12, and 13 as well as the various terminal types 21, 22, 23, and 24 over the semiconductor device of the present invention. In FIGS. 4A and 4B, the power supply pads 11, the ground pads 12, and the signal pads 13 are mounted at the same density over the semiconductor chip 10. The signal terminals 23, 24 are also the same density over the package substrate 20.

A first difference between FIG. 4A and FIG. 4B is the placement of the power supply terminal 21 and the ground terminal 22 over the package substrate 20. These two drawings differ in the point that in the related art, a double ring-shaped region is required for the power supply terminal 21 and the ground terminal 22, while in the present embodiment only one ring-shaped region is needed.

A second difference between FIG. 4A and FIG. 4B is the placement of the power supply pads 11 and the ground supply pads 12 over the semiconductor chip 10. These two drawings differ in the point that in the related art, a double ring-shaped region is required for the power supply pads 11 and the ground supply pads 12 while in the present embodiment only one ring-shaped region is needed.

Upon comparing FIG. 4A with FIG. 4B, one can see that the surface areas of the package substrate 20 and the semiconductor chip 10 in the present embodiment are reduced more than in the case of the related art. These reductions in size are linked to a reduction in size of the overall semiconductor device.

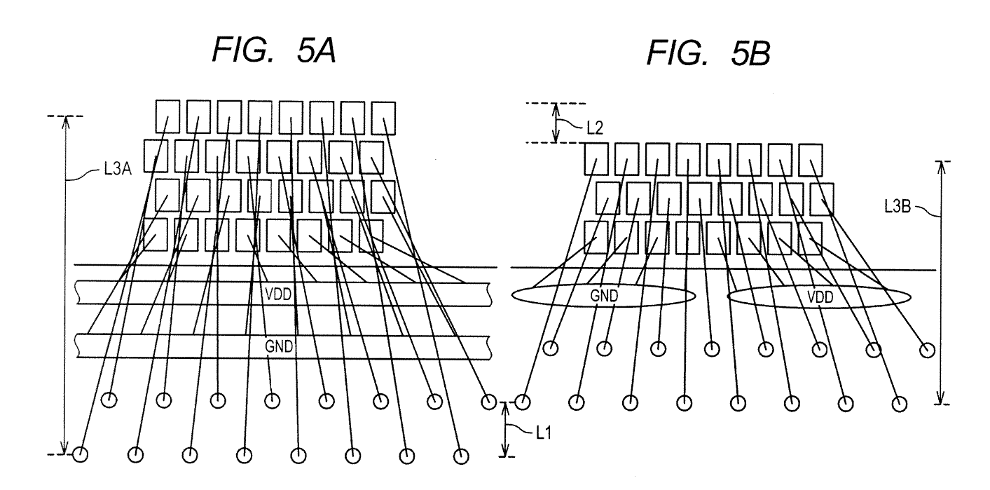

FIGS. 5A and 5B are a group of flat views showing the difference in semiconductor device sizes between the technology of the related art and the present invention. FIG. 5A is a flat view showing the structure of a portion of the semiconductor device technology of the related art. FIG. 5B is a flat view showing the structure of a portion of the semiconductor device technology of the present embodiment. In the semiconductor devices shown in FIGS. 5A and 5B, the total number of signal pads and the density are the same on both semiconductor chips. Moreover, the total number of signal pads and the density are the same on both package substrates.

The pitch of the signal terminals over the package substrate in the vertical direction here is set to L1. Compared to the related art technology, the size of the package substrate in the present embodiment can be reduced by the length L1 on each of the four sides so that even just this reduction serves to lower the cost.

Further, the pitch of the signal pads over the semiconductor chip in the vertical direction is set to L2. Compared to the related art technology, the size of the semiconductor chip can be reduced by the length L2 on each of the four sides, so that even just this reduction serves to lower the cost.

In the semiconductor device of the related art shown in FIG. 5A, the distance from the center of the outermost circumferential signal terminal over the package substrate to the innermost circumferential signal pad over the semiconductor chip is set as L3A. In the semiconductor device of the related art, the distance L3A is approximately equivalent to the length of the bonding wire group in the maximum length class for coupling the signal pad mounted over the innermost circumferential ring-shaped region over the semiconductor chip, to the signal terminal mounted over the outermost circumferential ring-shaped region over the package substrate.

In the semiconductor device of the present embodiment shown in FIG. 5B, the distance from the center of the outermost circumferential signal terminal over the package substrate to the innermost circumferential signal pad over the semiconductor chip is set in the same way as L3B. In the semiconductor device of the present embodiment, the distance L3B is approximately equivalent to the length of the bonding wire group in the maximum length class for coupling the signal pad mounted over the innermost circumferential ring-shaped region over the semiconductor chip, to the signal terminal mounted over the outermost circumferential ring-shaped region over the package substrate.

The present embodiment is capable of reducing the length and the total number of the required bonding wires so that even just this reduction serves to lower the cost.

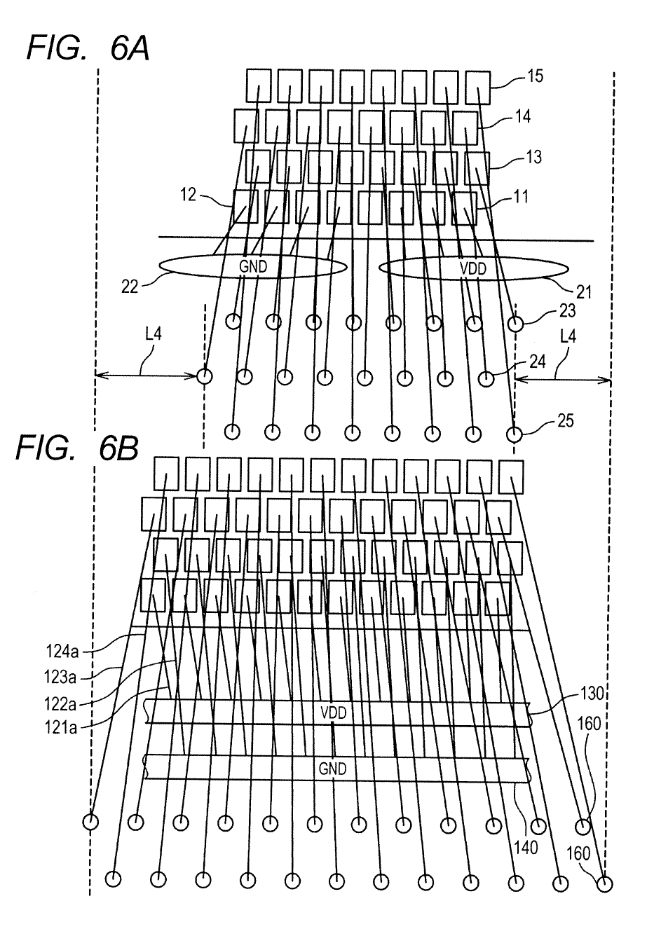

FIGS. 6A and 6B are a group of flat views showing the difference in semiconductor device sizes in the technology of the related art and the present invention. FIG. 6A is a flat view showing the partial structure of the semiconductor device of the present embodiment. FIG. 6B is a flat view showing the partial structure of the semiconductor device of the related art. FIGS. 6A and 6B show placements and total number of pads and terminals that is different from the case shown in FIG. 5. In other words, in the semiconductor device of the present embodiment as shown in FIG. 6A, the number of signal pads over the semiconductor chip have been increased more than in the case in FIG. 5B, and these signal pads have been mounted at four ring-shaped regions the same as in the related art. In the same way, in the semiconductor device of the present embodiment as shown in FIG. 6A, the number of signal terminals over the package substrate have been increased more than in the case in FIG. 5B, and these signal terminals have been mounted at four ring-shaped regions the same as in the related art. In both the semiconductor devices in FIG. 6A and FIG. 6B, the total number of signal pads and the density are the same. Moreover the total number of signal terminals and the density are the same over both the package substrates. However, among the four ring-shaped regions over the semiconductor device in FIG. 6A, a power supply pad 11 and ground pad 12 are mounted in the first ring-shaped region formed over the innermost circumference, and the first through third signal terminals 23-25 are mounted in the second through the fourth ring-shaped regions formed over the outer circumference of that first ring-shaped region. Also, among the four ring-shaped regions over the semiconductor device in FIG. 6B, a power supply ring-shaped terminal 130 is mounted in the first ring-shaped region formed over the innermost circumference, and a ground ring-shaped terminal 140 is mounted on the second ring-shaped region formed over the outer circumference of the terminal 130. A signal terminal 160 is mounted in the third and fourth ring-shaped regions formed even further to the outer circumference.

In the related art technology shown in FIG. 6B, the horizontal size of FIG. 6 must be expanded in order to hold the same number of signal pads and signal terminals as the present embodiment shown in FIG. 6A within these respective four ring-shaped regions. The reduced size that the present embodiment achieves in this direction as shown in FIG. 6A amounts to double the length L4 shown in FIG. 6.

So even with the same total number of multiple ring-shaped regions, the present embodiment is capable of reducing the size of the semiconductor device and can therefore be rendered at a lower cost.

### Second Embodiment

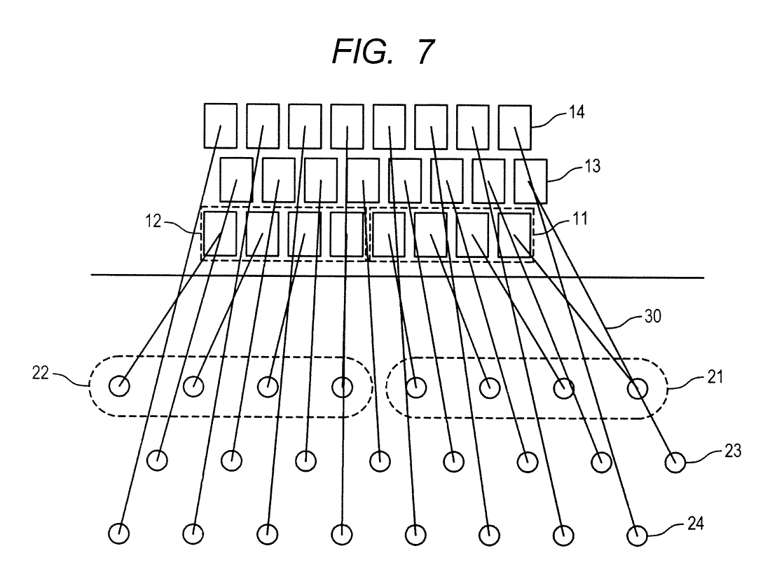

FIG. 7 is a flat view showing a fragment of the structure of the semiconductor device according to a second embodiment of the present invention. The semiconductor device of the embodiment shown in FIG. 7 is equivalent to the semiconductor device of the first embodiment of the present invention shown in FIG. 3 to which the following changes were added. Namely, one power supply terminal 21 of the package substrate 20 was added to each of the power supply pads 11 over the semiconductor chip. Also, one ground terminal 22 of the package substrate 20 was added to each of the ground pads 12 over the semiconductor chip.

Adding these changes makes the surface area occupied by the power supply terminal 21 and the ground terminal 22 over the package substrate 20 somewhat larger than the first embodiment of the present invention. However this change provides a further degree of freedom in placement of the power supply terminal 21 and the ground terminal 22 over the package substrate 20. Consequently, a further degree of freedom is obtained in the same way for the power supply pad 11 and the ground pad 12 over the semiconductor chip 10, and the design of the overall circuitry for the semiconductor chip 10 becomes easier.

In FIG. 7, the power supply terminals 21 are clustered together and the ground terminals are clustered together, however this arrangement is nothing more than one example and does not limit the present invention. The power supply terminal 21 and the ground terminal 22 for example may be placed at mutually alternating positions. Moreover, a power supply terminal 21 or a ground terminal 22 coupled to one power supply pad 11 or ground pad 12 in the present embodiment may be mounted in a mixed placement with the power supply terminal 21 or the ground terminal 22 jointly coupled to the power supply pads 11 or the ground pads 12 of the first embodiment of the present invention. However, the power supply terminals 21 and the ground terminals 22 of the present invention are preferably clustered in the innermost circumferential ring-shaped region over the package substrate. The power supply pads 11 or the ground pads 12 are preferably clustered in the outermost circumferential ring-shaped region over the semiconductor chip.

### Third Embodiment

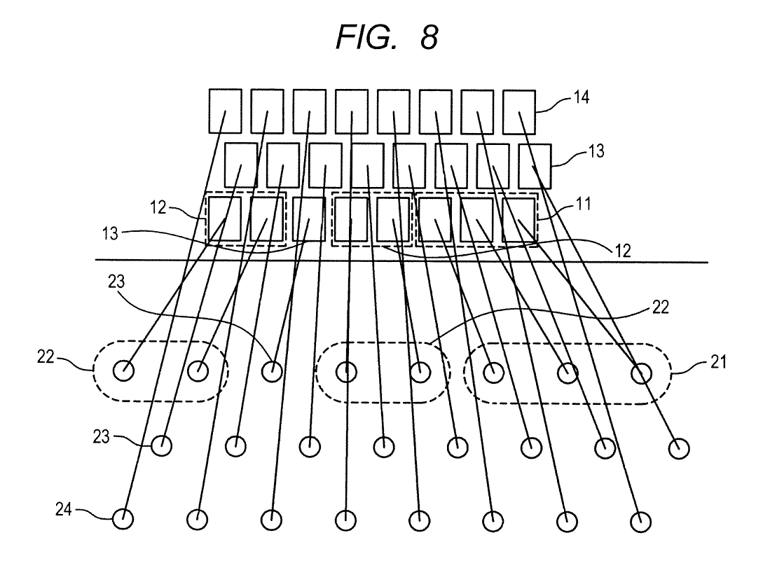

FIG. 8 is a flat view showing a fragment of the structure of the semiconductor device according to a third embodiment of the present invention. The semiconductor device of the present embodiment as shown in FIG. 8 is equivalent to the semiconductor device of the second embodiment of the present invention shown in FIG. 7 to which the following changes were added. Namely, a signal pad 13 is formed in the outermost circumferential ring-shaped region over the semiconductor chip 10; and the signal terminal 23 is formed in the innermost circumferential ring-shaped region over the package substrate 20.

The power supply pads 11 and the ground pads 12 over the semiconductor device of the present invention are basically clustered in the outermost circumferential ring-shaped region over the semiconductor chip. However, there are no prohibitions on making an exceptional placement of a portion of the signal pads 13 in the outermost circumferential ring-shaped region over the semiconductor chip. The power supply terminal 21 and the ground terminal 22 in the semiconductor device of the present invention can in the same way basically be clustered in the innermost circumferential ring-shaped region over the package substrate. However, there is no prohibition on making the exceptional placement of a portion of the signal terminals 23 in the outermost circumferential ring-shaped over the package substrate.

In the case in FIG. 8 in particular, the bonding wires 30 coupling the ground pads 12 to the ground terminals 22, enclose the left and right side of the bonding wire 30 coupling the exceptionally placed signal pad 13 and signal terminal 23. This placement renders the effect of boosting the noise resistance of the bonding wires 30 that couple the exceptionally placed signal pad 13 and signal terminal 23.

### Fourth Embodiment

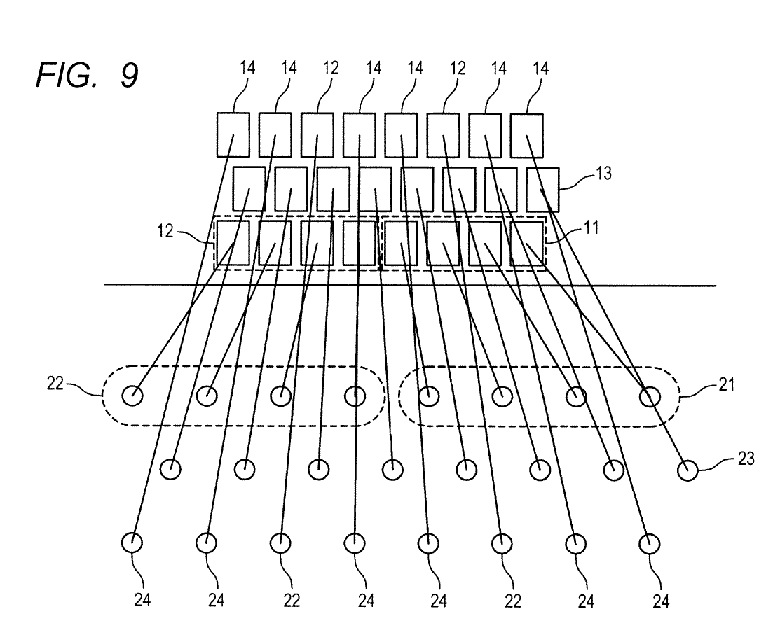

FIG. 9 is a flat view showing a fragment of the structure of the semiconductor device according to a fourth embodiment of the present invention. The semiconductor device of the present embodiment as shown in FIG. 9 is equivalent to the semiconductor device of the second embodiment of this invention shown in FIG. 7 to which the following changes have been added. Namely, a ground pad 12 was formed in the innermost circumferential ring-shaped region over the semiconductor chip 10, and the ground terminal 22 was formed in the outermost circumferential ring-shaped region over the package substrate 20.

In the semiconductor device of the present embodiment, the power supply pads 11 and the ground pads 12 are basically clustered in the outermost circumferential ring-shaped region over the semiconductor chip 10. However, the exceptional placement of a portion of the ground pads 12 in areas other than the outermost circumferential ring-shaped region over the semiconductor chip 10 is not prohibited. The power supply terminals 21 and the ground terminals 22 in the semiconductor device of the present invention are basically clustered in the innermost circumferential ring-shaped region over the package substrate 20. However, the exceptional placement of a portion of the ground terminals 22 in other than the innermost circumferential ring-shaped region over the package substrate 20 is not prohibited.

The bonding wire 30 coupling the ground terminal 22 and the ground pad 12 in the exceptional placement in FIG. 9 in particular, renders the effect of shielding the bonding wires 30 coupling the adjacent signal pads 14 and the signal terminals 24 on left and right. Utilizing this placement allows boosting the noise resistance in the bonding wire 30 that couples a portion of the signal pads and a portion of the signal terminals.

In the case of FIG. 9, the ground pad 12 was exceptionally placed in the outermost circumferential ring-shaped region over the semiconductor chip 10 however the ground pad 12 can in fact be placed in any ring-shaped region. In the case of FIG. 9 the exceptionally placed ground terminal 22 is in the same way placed in the outermost circumferential ring-shaped region over the package substrate 20, however the ground terminal 22 can in fact be placed in any ring-shaped region.

In the above description, various types of the terminals 11-15 and various types of the pads 21-25 formed in the ring-shaped region were arrayed linearly at each side of the semiconductor device, however this placement is at most only an example and a curved array for example can be utilized.

The configurations in these embodiments can be freely combined within a range that is not technically contradictory. In the semiconductor device of the present invention, the single power terminals 21, the joint power supply terminals 21, the single ground terminals, the joint ground terminals and the signal terminals 23 may for example be mixed together in the innermost circumferential rig-shaped region enclosing the mounted semiconductor chip 10 over the package substrate 20.

1. A semiconductor device comprising:
a semiconductor chip including a power supply pad, a ground pad, and a signal pad; and
a package substrate over which the semiconductor chip is mounted,
wherein the package substrate includes:
a first terminal group arrayed at the innermost circumferential ring-shaped region in the periphery of the semiconductor chip; and
a second terminal group in the periphery of the semiconductor chip and also arrayed at the outer side of the innermost circumferential ring-shaped region,
wherein the first terminal group includes:
a power supply terminal group coupled by way of bonding wire to the power supply pad; and
a ground terminal group coupled by way of bonding wire to the ground pad, and
wherein the second terminal group includes:
a signal terminal group coupled by way of the bonding wire to the signal pad.

2. The semiconductor device according to claim 1,
wherein the power supply terminal group includes:
a joint power supply terminal jointly coupled to the power supply pads, and
wherein the ground terminal group includes:
a joint ground terminal jointly coupled to the ground pads.

3. The semiconductor device according to claim 1,
wherein the first terminal group further including:
a signal terminal coupled by way of bonding wire to the signal pad.

4. The semiconductor device according to claim 1,
wherein the second terminal group further includes:
a shield terminal coupled by way of bonding wire to the ground pad.

5. The semiconductor device according to claim 1,
wherein the power supply terminal group, and the ground terminal group are alternately arrayed in the ring-shaped region at the innermost circumference.

6. The semiconductor device according to claim 1,
wherein the semiconductor chip includes:
a first pad group arrayed in the outermost circumferential ring-shaped region over the surface of the semiconductor chip; and
a second pad group arrayed in the inner side of the outermost circumferential ring-shaped region over the surface of the semiconductor chip,
wherein the first pad group includes:
a power supply pad group; and
a ground pad group, and
wherein the second pad group includes:
a signal pad group.

7. The semiconductor device according to claim 1,
wherein the package substrate further includes:
a ball grid array electrically coupled to the power supply terminal group, the ground terminal group, and the signal terminal group.

8. A semiconductor device comprising:
a semiconductor chip including a plurality of power supply pads and a plurality of ground pads;
a package substrate over which the semiconductor chip is mounted;
a first terminal group including a plurality of terminals arrayed along a specified direction in a region over the package substrate between the semiconductor chip and one side of the package substrate;
a second terminal group including a plurality of terminals arrayed along a specified direction in a region over the package substrate between the first terminal group and one side of the package substrate; and
bonding wires coupling at least the respective terminals of the first terminal group to the respective power supply pads and the respective ground pads,
wherein the first terminal group includes a power supply terminal group having a plurality of terminals coupled by way of bonding wires to the power supply pads, and a ground terminal group having a plurality of terminals coupled by way of bonding wires to the ground pad, the power supply terminal group and the ground terminal group being arrayed mounted alternately.

9. The semiconductor device according to claim 8,
wherein the semiconductor chip includes a plurality of signal pads different from the respective power supply pads, and the respective ground pads, and
wherein the second terminal group includes a signal terminal group comprising a plurality of terminals coupled by way of bonding wire to the signal pads.

10. The semiconductor device according to claim 9,
wherein the surface area at which the bonding wires for the respective terminals of the power supply terminal group and the respective terminals of the ground terminal group are bonded is larger than the surface area at which the bonding wires for the respective terminals of the signal terminal group are bonded.

11. The semiconductor device according to claim 10,
wherein the bonding wires are bonded to one terminal of the power supply terminal group.

12. The semiconductor device according to claim 10,
wherein the bonding wires are bonded to one terminal of the ground terminal group.

13. The semiconductor device according to claim 8,
wherein, between the power supply terminal group and the ground terminal group, there is at least one terminal coupled by way of the bonding wire to the signal pad.

14. The semiconductor device according to claim 9,
wherein there is at least one terminal within the second terminal group that is coupled by way of the bonding wire to the ground pad.

15. The semiconductor device according to claim 2,
wherein the second terminal group further includes:
a shield terminal coupled by way of bonding wire to the ground pad.

16. The semiconductor device according to claim 3,
wherein the second terminal group further includes:
a shield terminal coupled by way of bonding wire to the ground pad.
